(19) United States
(12) Patent Application Publication
(10) Pub. No.: US 2025/0063685 A1
(43) Pub. Date: Feb. 20, 2025

(54) MULTIFUNCTIONAL INTELLIGENT TEMPERATURE CONTROLLED SINGLET WITH WEARABLE ELECTRONIC TECHNOLOGY

(71) Applicant: Anhui Xinrentong Intelligent Technology Co., Ltd, Hefei (CN)

(72) Inventors: Junlin YE, Hefei (CN); Zhixin TAO, Hefei (CN); Ziyao DING, Hefei (CN); Hongli DONG, Hefei (CN)

(73) Assignee: Anhui Xinrentong Intelligent Technology Co., Ltd, Hefei (CN)

(21) Appl. No.: 18/614,762

(22) Filed: Mar. 25, 2024

(30) Foreign Application Priority Data
Aug. 15, 2023 (CN) 202322191567.9

(51) Int. Cl. H05K 7/20; G06F 1/16

(52) U.S. Cl. CPC H05K 7/20209; G06F 1/163; H05K 7/20136; H05K 7/2039

(57) ABSTRACT

A multifunctional intelligent temperature controlled singlet based on wearable electronic technology includes: a woven belt, wherein the woven belt is composed of two layers sewn up and down, and a control circuit is installed in the middle of the interlayer, including the shoulder and rear parts, extending downwards to the waist position of the human body, and connected through the insertion of the waistband. The woven belt is equipped with mounting holes; The cooling and heating device is installed on the mounting hole, and is connected to the power system hanging on the belt through a control circuit. The intelligent temperature controlled device is connected to the power system through an elastic circuit.

### CROSS-REFERENCE TO THE RELATED APPLICATIONS

This application is based upon and claims priority to Chinese Patent Application No. 202322191567.9, filed on Aug. 15, 2023, the entire contents of which are incorporated herein by reference.

### TECHNICAL FIELD

The present disclosure is related to the field of wearable apparatus, more specifically, it is A Multifunctional Intelligent Temperature Controlled Singlet with Wearable Electronic Technology.

### BACKGROUND

With the development of cooling technology, people can now create a refreshing indoor working environment through air conditioning equipments even in hot summers. However, for those who works outdoors or in high-temperature, it is impossible for them to avoid stifling heat.

The high-temperature environment is widely believed to have a negative effect on the production efficiency for high-temperature workers and affect their health. For example, traffic police officers on duty outdoors will face high temperatures of 35° C. or even above 40° C.; Some workers in the metallurgical industry inevitably need to work in a workshop at 60-70° C.; Firefighters will enter into the fires above 80° C. to carry out rescue work in the spot. For people who work in such high-temperature environments for a long time, their physiological functions, especially temperature regulation, water and salt metabolism, and blood circulation, are prone to problems. Once excess heat cannot be dissipated in time through the body's self-regulation, it will lead to an increase in body temperature and excessive sweating. Moreover, due to the ballooning of blood vessels on the surface of the skin, when blood circulation accelerates, it will lead relatively insufficient blood supply to the brain center, making it difficult for workers to concentrate. This will reduce their work efficiency and affect their ability to judge on one hand, or severely on the other, will lead to heatstroke or more serious physical problems, greatly escalating the risk of accidents. For firefighters and metallurgical workers, accidents generally mean that their lives are at risk.

Therefore, in a high-temperature environment without air conditioning or other cooling equipments, how to reduce body temperature through the apparatuses carried by oneself and combat the troubles brought by the high-temperature environment is a topic for which researchers all over the world are carrying out their research. In order to address the various discomforts caused by the physical exertion of workers in high heat environments due to heat stress effects, researchers from all countries have developed various cooling work clothes. At present, the main ones used to improve body heat radiating are through conduction, convection, radiation, evaporation and other forms to achieve cooling effects. However, due to the limitations in technology and other factors, the common singlets cooled by air compression have defects of high cost, heavy weight and inconvenient mobility. While the cooling singlet with a micro fan to blow sweat and heat, has a bulky appearance and cannot meet the body's cooling needs in hot weather. The cooling singlet cooled by solid ice and liquid water circulation has a large weight, although with short cooling time, requires early cooling to the ice bag. The singlet that is injected with cooling gel or phase changing material as a cold source needs to be cooled in advance, which is inconvenient.

### SUMMARY

In order to effectively solve the problem of poor effectiveness in the use of existing cooling singlets, the present disclosure aims to provide a Multifunctional Intelligent Temperature Controlled Singlet with Wearable Electronic Technology, which can effectively reduce the core temperature for the human body. It is lightweight and portable that can be adapted to various working conditions, and can maintain a longer time for cooling work even when the wearer is lightly burdened.

The present disclosure will solve technical problems through the following technologies:

The woven belt, which is composed of two layers sewn together, with a control circuit installed in the middle of the interlayer, consists of the shoulder and rear parts, extending downwards to the waist of the body, and connected through the insertion of the waistband. The woven belt is equipped with mounting holes;

The cooling and heating device: It is installed on the mounting hole and is connected to the power system hanging on the waistband through a control circuit;

The intelligent temperature controlled device: It is connected to the power system through an elastic circuit.

Technology evolution of the present disclosure:

Preferably, the aforesaid cooling and heating device is comprised of a shell which is embedded in the mounting hole. The aforesaid shell is provided with an air inlet and outlet;

In the aforesaid shell electronic fans, radiators, electronic cooling and heating chips, thermistors, graphene sheets, and heat conductors are installed in turn;

The aforesaid fan is set next to the radiator. The air from the air inlet is blown towards the radiator, and then blown out through the air outlet;

The aforesaid thermistor is integrated into the electronic cooling and heating chips, near the graphene sheet. It senses the temperature of the electronic cooling and heating chips;

The aforesaid graphene sheet is used for heat conduction, located between the heat conductive plate and the electronic cooling and heating chip;

The aforesaid heat conductive plate is on the side close to the human body, with a layer of silicone coating on the surface.

Preferably, the copper conductive plates are set at both ends of the aforesaid cooling and heating chips.

Preferably, the aforesaid shell is comprised of the first shell and a second shell, with the former located on the outer side of the woven belt and the latter on the inner side of it. There is a slit at the bottom of the second shell, in which the heat conductive plate is clamped in contact with the surface of human body. The woven belt goes between the first shell and the second shell, with a mounting hole to connect the internal space of the first and second shells.

Preferably, the aforesaid cooling and heating devices consist of two different types of forward radiating and lateral radiating;

In the mode of forward radiating, the air inlet is located on the side wall of the second shell and the air outlet is located on the top of the first shell. The electric fan and radiator are arranged vertically;

In the mode of lateral radiating, the air inlet is located at the top of the first shell and the air outlet is located on the side wall of the first shell. The electric fan and radiator are arranged horizontally.

Preferably, the aforesaid woven belt is equipped with circular nails, and the outer covering of the intelligent temperature controlled device is equipped with stainless steel springs on which a slot for installing the circular nail is designed. Thus, the intelligent temperature controlled device is installed on the woven belt through stainless steel spring and circular nails.

Preferably, the intelligent temperature controlled device is equipped with a liquid crystal display. The thermistor senses the temperature on the surface of the electronic cooling and heating chips and feeds it back to the liquid crystal display. The screen will display the temperature of the electronic cooling and heating chips perceived by the thermistor. Through the circuit board by a thin film switch on the outer covering of the controller, users can control the current and voltage of the electronic cooling and heat chips, thereby to control the temperature of the electronic cooling chip. The beneficial effects of the present disclosure will be in the following:

1. The present disclosure is a Multifunctional Intelligent Temperature Controlled Singlet with Wearable Electronic Technology. It uses the design of the woven belt as a platform for carrying cooling modules to reduce production cost and lighten for carrying easily, which completely breaks the fixed mind-set for traditional singlets. It can be worn externally and internally, and can be integrated with uniforms under various working conditions, including outdoor leisure activities and jobs;

2. The present disclosure is compact to avoid the crucial body parts such as the cervical and lumbar vertebraes that are vulnerable to physical health according to the body acupoints. At the same time, its system modules are designed to be able to move and adjust in the direction of the woven belt. Different people can move and adjust the system modules freely according to their own needs, ensuring that the best body acupoints and the best position suitable for themselves are found, meeting the individual's cooling needs;

3. The present disclosure is equipped with copper conductive plates at both ends of the electronic cooling and heating chips, which greatly improves the utilization efficiency of cooling capacity for the semiconductor. It greatly reduces the thickness of the electronic cooling and heating chips, making it more efficient, light and plastic.

### BRIEF DESCRIPTION OF THE DRAWINGS

FIG. 1, the Example 1, shows the front diagram of the Multifunctional Intelligent Temperature Controlled Singlet with Wearable Electronic Technology;

FIG. 2, the Example 1, shows the rear diagram of the Multifunctional Intelligent Temperature Controlled Singlet with Wearable Electronic Technology;

FIG. 3 is a diagram of the exploded drawings of the cooling and heating device for forward radiating;

FIG. 4, the Example 2, shows the front diagram of the Multifunctional Intelligent Temperature Controlled Singlet with Wearable Electronic Technology;

FIG. 5, the Example 2, shows the rear diagram of the Multifunctional Intelligent Temperature Controlled Singlet with Wearable Electronic Technology;

FIG. 6 is a diagram of the exploded drawings of the cooling and heating device for lateral radiating;

FIG. 7 is a diagram of the exploded drawings of the intelligent temperature controlled device;

Numbers in the figures: 10 woven belt, 11 mounting hole, 12 cooling and heating device, 13 waistband, 14 intelligent temperature controlled device, 15 power system, 16 the first shell, 17 the second shell, 18 air inlet, 19 air outlet, 20 electronic fan, 21 radiator, 22 thermistor, 23 electronic cooling and heating chip, 24 graphene sheet, 25 heat conductive plate, 26 copper conductive plate, 27 round nail, 28 stainless steel spring, 29 slot, 30 liquid crystal display, 31 thin film switch, 32 the circuit board, 33 multi-functional storage bag, 34 silicone coating, 35 controlled circuit.

### DETAILED DESCRIPTION OF THE EMBODIMENTS

In order to make personnels in this field of technology to understand better the technical proposal in this application, a clear and complete description of the technical proposal in the Examples of this application will be provided below with attached figures. Obviously, the described examples are not all of the embodiments in the present disclosure, but a part of them.

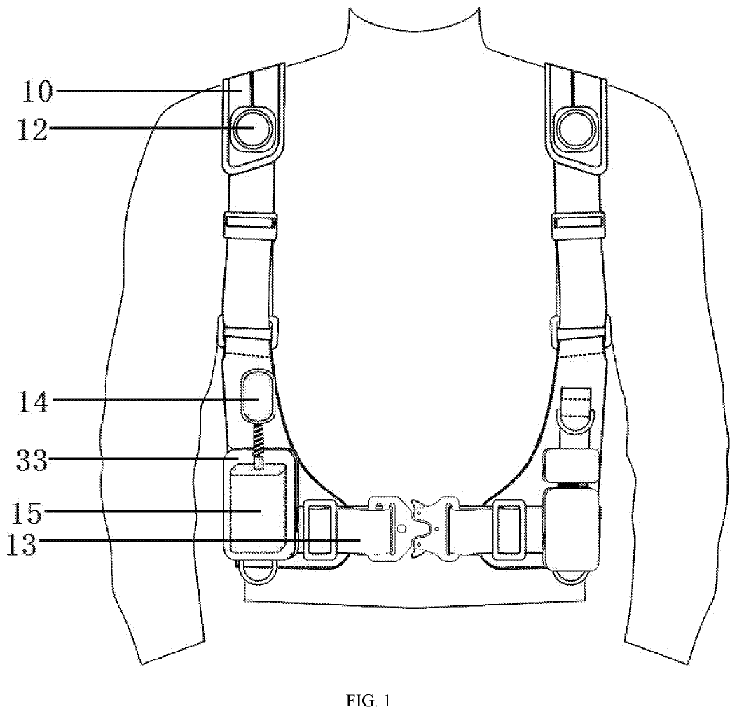

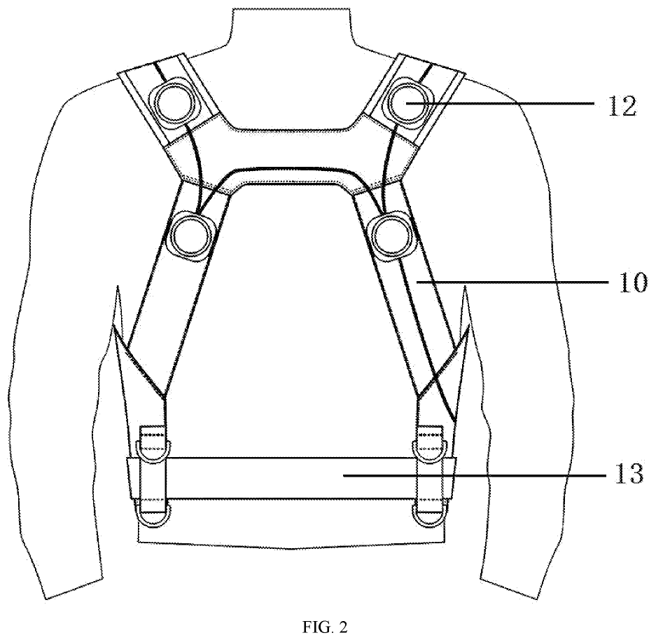

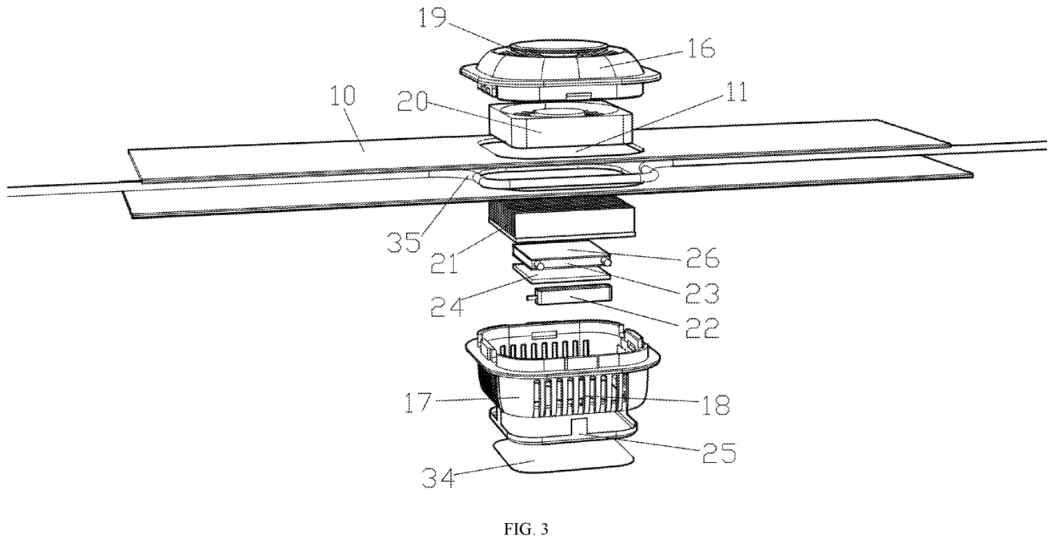

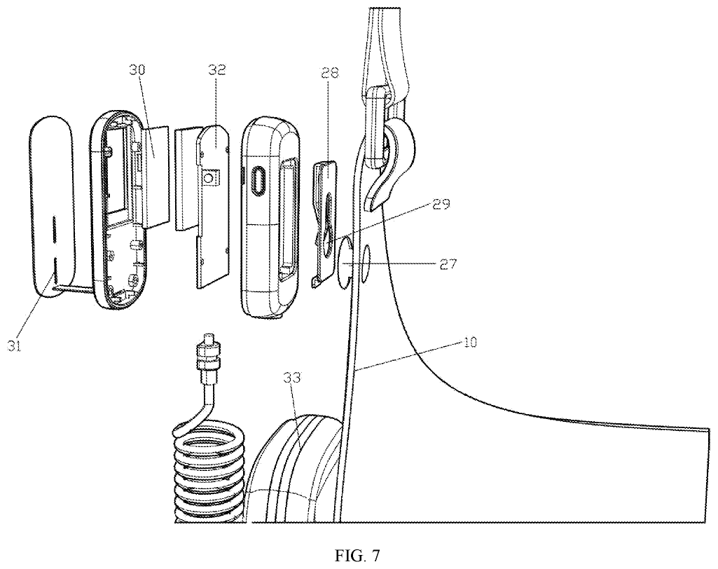

Example 1, as shown in FIGS. 1, 2, 3 and 7, provides a Multifunctional Intelligent Temperature Controlled Singlet with Wearable Electronic Technology, comprising of:

Woven belt 10, the aforesaid which is composed of two layers sewn together, with a control circuit 35 installed in the middle of the interlayer, consists of the shoulder and rear parts, extending downwards to the waist of the body, and connected through the insertion of the waistband 13. The woven belt 10 is equipped with mounting holes 11; In this Example, the woven belt 10 is designed as the structure of telescopic adjustment, which can effectively meet the requirements of different human heights and body types for customization. A single product can cover the needs of every individual with no need for multiple sizes, thus solving the problem of mass production.

Mounting hole 11 should be avoided towards the crucial body parts such as the cervical and lumbar vertebraes that are vulnerable to physical health according to the body acupoints. At the same time, its system modules are designed to be able to move and adjust in the direction of the woven belt 10. Different people can move and adjust the system modules freely according to their own needs, ensuring that the best body acupoints and the best positions suitable for themselves are found.

The cooling and heating device 12: It is installed on the mounting hole 11 and is connected to the power system hanging on the waistband 13 through a control circuit 15;

The electronic module for cooling and heating system is designed as an integrated part with the woven belt 10, embedded inside it. The radiator is placed above the woven belt 10, and the cooling device is placed below the woven belt 10. The cooling device should maintain a certain distance from the woven belt 10. Through the integrated design with the woven belt 10, the cooling device is tightly attached to the body.

The aforesaid cooling and heating device 12 is comprised of a shell which is embedded in the mounting hole 11. The shell is provided with an air inlet 18 and outlet 19.

In the aforesaid shell electronic fans 20, radiators 21, thermistors 22, electronic cooling and heating chips 23, graphene sheets 24, and heat conductors 25 are installed in turn;

The aforesaid electric fan 20 is set next to the radiator 21. The air from the air inlet is blown towards the radiator 21, and then blown out through the air outlet;

The aforesaid thermistor 22 is integrated into the electronic cooling and heating chips, near the graphene sheet. The thermistor 22 senses the surface temperature of the electronic cooling and heating chips 23;

Traditional thermistors are placed between graphene sheets and heat conducting sheets, with low conductive efficiency and a temperature difference of 4-5° C. when the temperature is transmitted to the control board. For example, the cold surface temperature of the cooling sheet is 18° C., while the temperature feedback from the thermistor to the control board is 22-23° C.

This technical proposal integrates thermistors into the interior of electronic cooling and heating chips, and setting them closely against the cold surface of the cooling and heating chips, directly feedback the temperature to the control board.

Firstly, achieving integrated design makes the transmission circuit less complex;

Secondly, Temperature conduction is more sensitive and precise, for example, if the cold surface temperature of the cooling plate is 18° C., the temperature transmitted by the thermistor to the control board would be 18° C. as well;

Thirdly, the higher efficiency, the lower power consumption makes the control board to perceive temperature more accurately, thereby to control current and voltage, reduce power loss and improve endurance.

The aforesaid graphene sheet 24 is made of pure graphene material. The graphene thermal conductivity technology is used for heat conduction. The graphene sheet is located between the heat conductive plate 25 and the electronic cooling and heating chips.

The heat/cold capacity of the chip can be evenly diffused to the heat conductive plate by using graphene sheets, making radiating balance to the conduction area.

The use of graphene sheets 24 greatly improves the efficiency of cold capacity utilization for semiconductor, bringing the more efficient and balanced to heat conduction, solving the problem of low cold capacity utilization for traditional semiconductors.

The aforesaid heat conductive plate 25 is on the side close to the human body with a layer of silicone coating 34 on the surface to conduct the cold or heat to the human body.

The use of skin friendly (silicone) materials avoids direct contact between metal conductive plates and human flesh, making cold and heat conduction more balanced, providing a more comfortable body feeling, and preventing condensation.

Electronic cooling and heating chips: TEC, also known as thermoelectric cooler, has direct and efficient heat exchange characteristics, which can quickly and efficiently transfer heat, mainly achieving cooling and heating functions. Copper conductive plates 26 are set at both ends of the TEC;

Compared to the conventional cooling equipments, the electronic cooling equipments are simple in structure, small in size and light in weight. They are safe and stable with low cost of maintenance;

According to conventional technology in TEC the ceramic or aluminum sheets are preferably used at both ends of the TEC, which makes it large in volume, high in thickness, and low in heat conversion efficiency; This proposal, by setting copper conductive plates 26 at both ends of the TEC, greatly improves the efficiency of cooling capacity utilization for semiconductor. It greatly reduces the thickness of the TEC, which makes it more efficient, light and plastic;

Radiator 21: It is mainly used for ventilation and heat dissipation. Copper plates are used as the main material of radiator 21, which has better heat radiating effect than traditional aluminum materials. At the same time, the technics of the arched (undulation) matrix arrangement has the characteristics of large radiating area and good air circulation effect. It achieves rapid radiating without increasing the volume of radiator 21, greatly improving the radiating efficiency;

The traditional cooling plates are mainly put the aluminum blades in vertical order, which has drawbacks such as large in volume, high in thickness, and poor in radiating effect, because the radiating effect is directly proportional to the area, height, and volume of the cooling plates. In this technical proposal the radiator 21 is made of copper with arched matrix structure of an air passage which has technical advantages of small in volume, thin in thickness, strong in air circulation, and highly efficient in radiating. It is suitable for multiple settings and has strong plasticity;

The aforesaid woven belt 10 is equipped with round nails 27, and the outer covering of the intelligent temperature controlled device 14 is equipped with a stainless steel spring 28 on which a slot 29 for installing the round nail 27 is designed. Thus, the intelligent temperature controlled device is installed on the woven belt 10 through the stainless steel spring and the round nail 27.

The intelligent temperature controlled device 14 is equipped with a liquid crystal display 30. The thermistor 22 senses the temperature on the surface of the electronic cooling and heating chips 23 and feeds it back to the liquid crystal display 30. The screen will display the temperature of the electronic cooling and heating chips 23 perceived by the thermistor 22. Through the circuit board 32 by a thin film switch 31 on the outer covering of the controller, users can control the current and voltage of the electronic cooling and heat chips 23, thereby to control the temperature of the electronic cooling chips.

The intelligent temperature controlled device 14, the aforesaid which is connected to the power system 15 through an elastic circuit.

When not in use, it is directly fixed on the woven belt 10. While in use, it can be taken out at any time and stretched to a comfortable position for individuals through elastic lines.

The aforesaid shell is comprised of the first shell 16 and a second shell 17, with the former 16 located on the outer side of the woven belt 10 and the latter on the inner side of the woven belt 10. There is a slit at the bottom of the second shell, in which a heat conductive plate 25 is clamped in contact with the surface of physical body. The woven belt 10 goes between the first shell 16 and the second shell, with a mounting hole 11 to connect the internal space of the first and second shells 17.

In this example, the interchangeable mobile power in the market is used as power system 15, which has the features of universal adaptability, waterproofing, small in size, light in weight, low in power consumption, long in endurance, and overload in protection, etc.

The power system is compatible with conventional mobile power sources on the market. In case of emergency situations such as power damage, users can replace it with any conventional mobile power source, bringing more convenience to them.

In the example the multi-functional storage bag 33 is hung on the waistband 13, while the power is put inside the multi-functional storage bag 33.

In the example, the cooling and heating device 12 is in the mode of forward radiating, the air inlet is located on the side wall of the second shell and the air outlet is located on the top of the first shell 16. The electric fan 20 and the radiator 21 are arranged vertically;

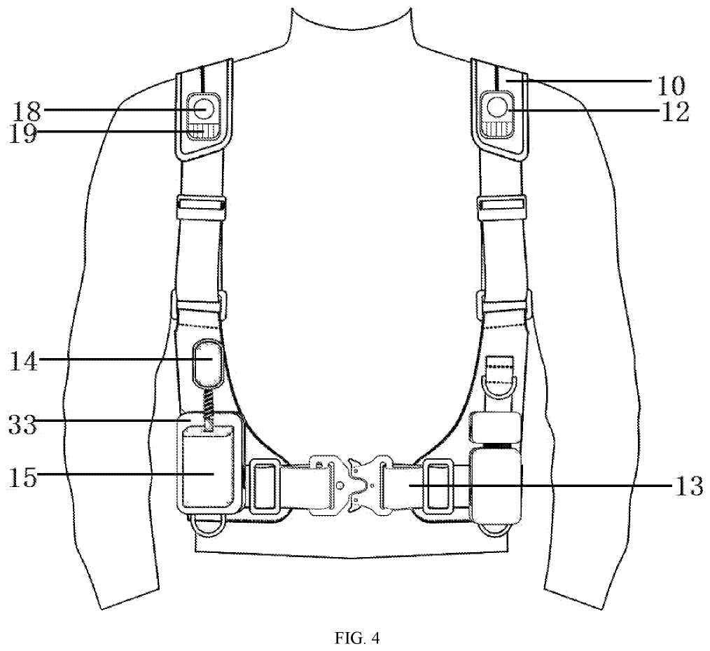

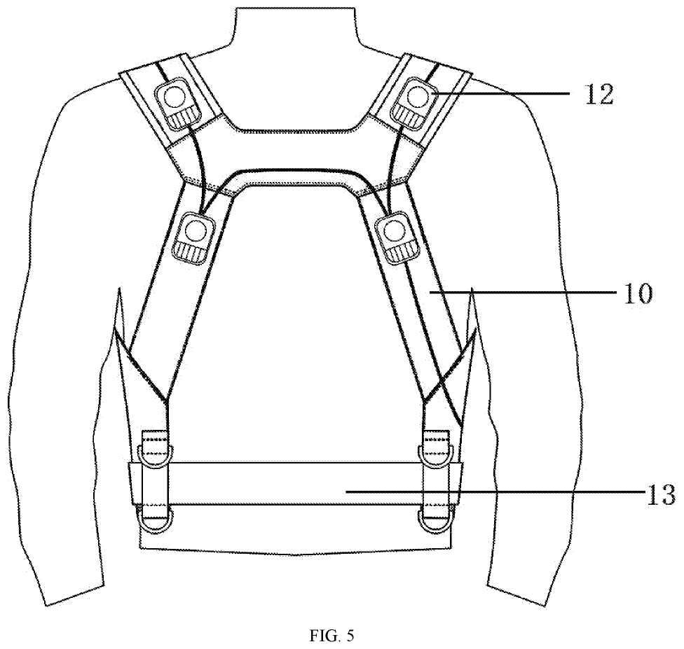

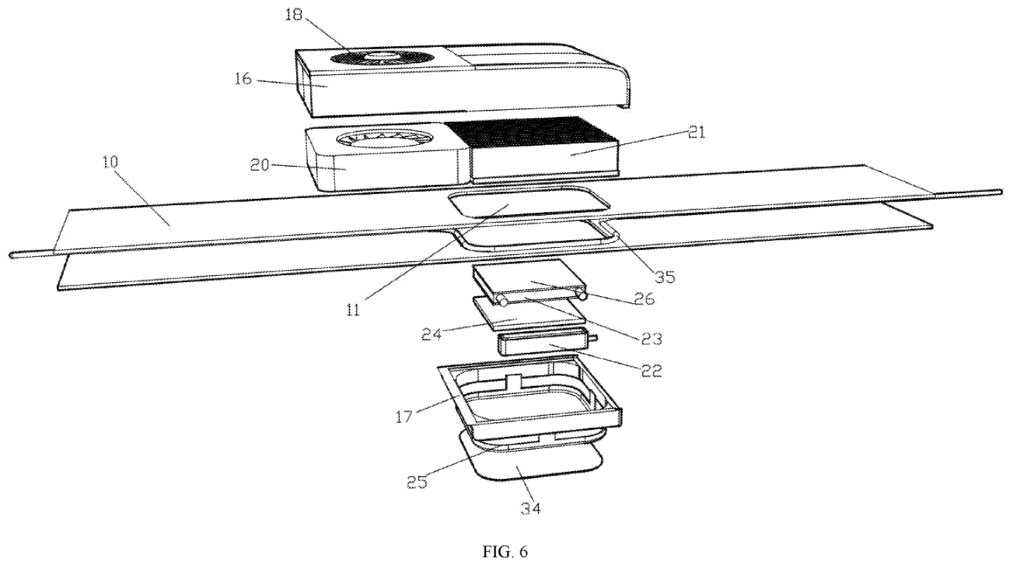

In Example 2, on the basic structure of Example 1, the cooling and heating device 12 is replaced with lateral radiating, as shown in FIGS. 4-7. In the mode of lateral radiating, the air inlet is located at the top of the first shell 16 and the air outlet is located on the side wall of the first shell 16. The electric fan 20 and the radiator 21 are arranged horizontally.

The electric fan 20 is a turbo centrifugal mute fan, which is arranged parallel to radiator 21. The air outlet is seamlessly connected to radiator 21, and the air is quickly centred and blown into radiator 21. With the help of the arched matrix air passage of copper radiator 21, rapid ventilation, radiating and cooling are thus achieved.

Conventional radiating fans are mainly axial flow fans, which is designed a direct exhaust with induced draft on both sides and top. Such fans usually have a large volume, high thickness and noise with poor radiating effect;

The turbo centrifugal mute fan in the Example is thinner and smaller than the conventional axial flow fans. At the same time, a lateral radiating mode is adopted to accelerate the air circulation with the help of an arch matrix air passage structure made of copper, which makes the radiating efficiently. The reduction in thickness makes it visually more beautiful and flexible.

In the present disclosure, unless there are clear provisions and limitations, the features are intertwined and may not necessarily exist independently. The above display and description include the present disclosure's basic principles, main features, and advantages. Technicians engaged in this field should be aware that the present disclosure is not limited to the limitations of the above Examples. The above Examples and instructions are only preferred embodiments of the present disclosure, and are not intended to confine the present disclosure to become the only option. Under the requirements of spirit and extent for the present disclosure, it can be altered and optimized further. Any improvements and optimizations made to the present disclosure are all required within the extent of the claimed protection. The specific extent of protection required by the present disclosure is defined by the attached claims and their equivalents.

What is claimed is:

1. A multifunctional intelligent temperature controlled singlet with wearable electronic technology, comprising:
a woven belt, wherein the woven belt comprises two layers sewn together, with a control circuit installed in a middle of an interlayer, comprises shoulder and rear parts, extending downwards to a waist of a body, and connected through an insertion of a waistband; the woven belt is equipped with mounting holes;
a cooling and heating device, wherein the cooling and heating device is installed on the mounting hole and is connected to a power system hung on the waistband through the control circuit;
an intelligent temperature controlled device, wherein the intelligent temperature controlled device is connected to the power system through an elastic circuit.

2. The multifunctional intelligent temperature controlled singlet with the wearable electronic technology according to claim 1, wherein the cooling and heating device comprises a shell embedded in the mounting hole; the shell is provided with an air inlet and outlet;
in the shell, electronic fans, radiators, electronic cooling and heating chips, thermistors, graphene sheets, and heat conductive plates are installed in turn;
the electric fan is set next to the radiator; the air from the air inlet is blown towards the radiator, and blown out through the air outlet;
the thermistor is integrated into the electronic cooling and heating chip, adjacent to the graphene sheet; the thermistor senses a temperature of the electronic cooling and heating chips;
the graphene sheet is configured for heat conduction, located between the heat conductive plate and the electronic cooling and heating chip;
the heat conductive plate is on a side adjacent to the human body, with a layer of silicone coating on a surface.

3. The multifunctional intelligent temperature controlled singlet with the wearable electronic technology according to claim 2, wherein the copper conductive plates are set at both ends of the electronic cooling and heating chip.

4. The multifunctional intelligent temperature controlled singlet with the wearable electronic technology according to claim 2, wherein the shell comprises a first shell and a second shell, wherein the first shell is located on an outer side of the woven belt and the second shell is on an inner side of the woven belt; there is a slit at a bottom of the second shell, wherein the heat conductive plate is clamped in the slit in contact with a surface of the human body; the woven belt goes between the first shell and the second shell, with a mounting hole to connect an internal space of the first and second shells.

5. The multifunctional intelligent temperature controlled singlet with the wearable electronic technology according to claim 4, wherein two different cooling and heating devices comprise forward radiating and lateral radiating;
in the mode of forward radiating, the air inlet is located on a side wall of the second shell and the air outlet is located on a top of the first shell; the electric fan and the radiator are arranged vertically;
in the mode of lateral radiating, the air inlet is located at the top of the first shell and the air outlet is located on a side wall of the first shell; the electric fan and the radiator are arranged horizontally.

6. The multifunctional intelligent temperature controlled singlet with the wearable electronic technology according to claim 2, wherein the intelligent temperature controlled device is equipped with a liquid crystal display; the thermistor senses a temperature on a surface of the electronic cooling and heating chips and feeds the temperature back to the liquid crystal display; the screen will display the temperature of the electronic cooling and heating chips perceived by the thermistor; through a circuit board by a thin film switch on an outer covering of a controller, users are allowed to control a current and voltage of the electronic cooling and heat chips to control the temperature of the electronic cooling and heating chip.

7. The multifunctional intelligent temperature controlled singlet with the wearable electronic technology according to claim 1, wherein the woven belt is equipped with round nails, and an outer covering of the intelligent temperature controlled device is equipped with a stainless steel spring, wherein a slot for installing the round nail is designed on the stainless steel spring; the intelligent temperature controlled device is installed on the woven belt through the stainless steel spring and the round nail.
